(19) United States
(12) Patent Application Publication
(10) Pub. No.: US 2010/0089748 A1
(43) Pub. Date: Apr. 15, 2010

(54) CONTROL OF EROSION PROFILE ON A DIELECTRIC RF SPUTTER TARGET

(76) Inventors: JOHN C.FORSTER, San Francisco, CA (US); Daniel J. Hoffman, Saratoga, CA (US); John A. Pipitone, Livermore, CA (US); Xianmin Tang, San Jose, CA (US); RongJun Wang, Cupertino, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/252,224

(22) Filed: Oct. 15, 2008

(51) Int. Cl. C23C 14/34; B32B 37/12

(52) U.S. Cl. 204/298.16; 204/298.02; 156/60

(57) ABSTRACT

The present invention generally includes a sputtering target assembly that may be used in an RF sputtering process. The sputtering target assembly may include a backing plate and a sputtering target. The backing plate may be shaped to have one or more fins that extend from the backing plate towards the sputtering target. The sputtering target may be bonded to the fins of the backing plate. The RF current utilized during a sputtering process will be applied to the sputtering target at the one or more fin locations. The fins may extend from the backing plate at a location that corresponds to a magnetic field produced by a magnetron that may be disposed behind the backing plate. By controlling the location where the RF current is coupled to the sputtering target to be aligned with the magnetic field, the erosion of the sputtering target may be controlled.

### BACKGROUND OF THE INVENTION

1. Field of the Invention

Embodiments of the present invention generally relate to Physical Vapor Deposition (PVD) devices, and more specifically to RF magnetron sputtering devices.

2. Description of the Related Art

PVD processes are generally used to deposit a layer of material onto a substrate in a processing chamber. A body of material, or target, is attached to a backing plate. A power source is coupled to the backing plate, or directly to the sputtering target, to provide electrical current to the target. The electrical current ignites processing gases within the processing chamber into a plasma. The sputtering target is bombarded with ions from the plasma that cause atoms of the sputtering target to be sputtered from the sputtering target.

One form of sputtering is reactive sputtering. In reactive sputtering processes, the sputtering target may comprise a material, such as a metal, that reacts with the processing gas to form a layer on the substrate that has a different composition than the composition of the sputtering target. For example, when depositing a titanium nitride film by reactive sputtering, a sputtering target comprising titanium may be electrically biased with a DC current. The processing gas may contain an inert gas, such as argon, and additionally a reactive gas such as nitrogen. The processing gas is ignited into a plasma and the titanium is sputtered from the target. The titanium and nitrogen bond and deposit on the substrate as titanium nitride.

When depositing a film by reactive sputtering, it may be difficult to predict the exact composition of the deposited film. For example, when depositing titanium nitride, the deposited titanium nitride layer may have varying concentration of nitrogen throughout the layer. The varying concentration of nitrogen may not be repeatable across a plurality of substrates.

Therefore, there is a need in the art for a sputtering target that may be used to reactively sputter material onto a substrate with a predetermined and repeatable composition.

### SUMMARY OF THE INVENTION

The present invention generally includes a sputtering target assembly that may be used in an RF sputtering process. The sputtering target assembly may include a backing plate and a sputtering target. The backing plate may be shaped to have one or more fins that extend from the backing plate towards the sputtering target. The sputtering target may be bonded to the fins of the backing plate. The RF current utilized during a sputtering process will be applied to the sputtering target at the one or more fin locations. The fins may extend from the backing plate at a location that corresponds to a magnetic field produced by a magnetron that may be disposed behind the backing plate. By controlling the location where the RF current is coupled to the sputtering target to be aligned with the magnetic field, the erosion of the sputtering target may be controlled.

In one embodiment, a sputtering target assembly is disclosed. The assembly includes a backing plate body having one or more fins centered and coupled thereon, a filler material coupled to the backing plate body, the inner surface of the one or more fins, and outer surface of the one or more fins, and a sputter target coupled to the filler material and bottom surface of the one or more fins. The one or more fins include an inner surface, an outer surface, and a bottom surface.

In another embodiment, a sputtering target assembly is disclosed. The assembly includes a backing plate body having one or more fins and a sputter target coupled to the backing plate body. The one or more fins may be configured to contact a sputter target centered and coupled thereon. The one or more fins include an inner surface, an outer surface, and a bottom surface. The sputter target includes one or more recesses configured to receive the one or more fins.

In another embodiment, a method of assembling a sputter target assembly comprises applying bonding material to one or more of a backing plate body and a sputtering target and compressing the backing plate body and sputtering target together. The backing plate body includes one or more fins. The fins extend from a first surface of the backing plate body and substantially circumscribe the center axis of the backing plate body.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional plan view of one embodiment of a substrate processing chamber.

FIG. 2A is a cross sectional view of one embodiment of a target assembly.

FIG. 2B is a cross sectional view of the target assembly of FIG. 2A with a magnetic field illustratively shown.

FIG. 3 is a cross sectional view of another embodiment of a target assembly.

FIG. 4 is a bottom view of a target assembly according to one embodiment of the invention.

FIG. 5 is a cross sectional view of another embodiment of a target assembly with a magnetic field illustratively shown.

FIG. 6 is a cross sectional view of another embodiment of a target assembly.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally includes a sputtering target assembly that may be used in an RF sputtering process. The sputtering target assembly may include a backing plate and a sputtering target. The backing plate may be shaped to have one or more fins that extend from the backing plate towards the sputtering target. The sputtering target may be bonded to the fins of the backing plate. The RF current utilized during a sputtering process will be applied to the sputtering target at the one or more fin locations. The fins may extend from the backing plate at a location that corresponds to a magnetic field produced by a magnetron that may be disposed behind the backing plate. By controlling the location where the RF current is coupled to the sputtering target to be aligned with the magnetic field, the erosion of the sputtering target may be controlled.

The invention will be described below with referenced to a PVD chamber. A PVD chamber that may be utilized to practice the invention is available from Applied Materials, Inc., Santa Clara, Calif. It is to be understood that the invention may have utility in other processing chambers, including those sold by other manufacturers.

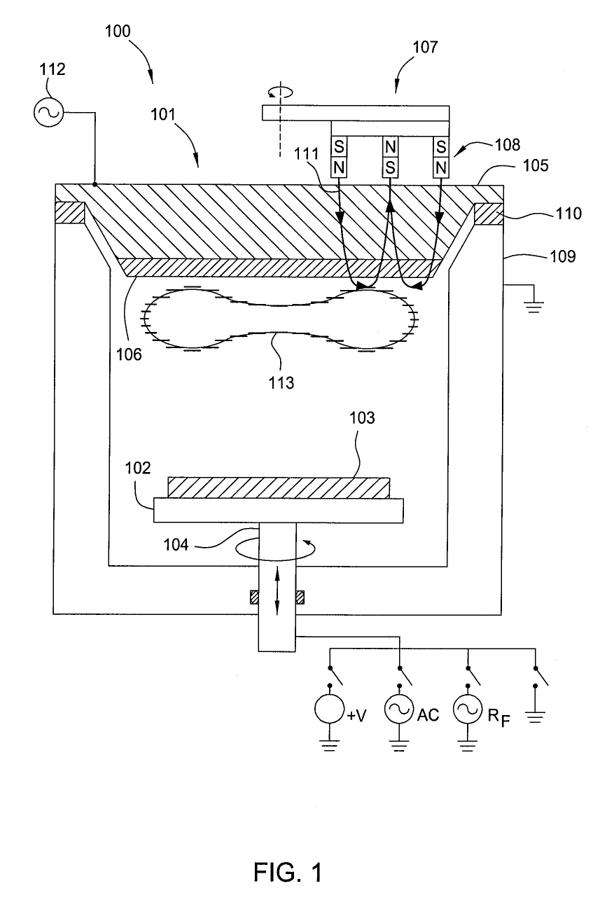

FIG. 1 is a cross sectional plan view of one embodiment of a substrate processing chamber 100. The processing chamber 100 may comprise chamber walls 109 that enclose a processing area. The chamber walls 109 may be grounded. In one embodiment, the chamber walls 109 may comprise aluminum, an aluminum alloy, or other suitable material. In one embodiment, the chamber walls 109 may comprise stainless steel. A substrate support 102, disposed within the processing area, may be disposed opposite to a target assembly 101 for supporting a substrate 103 thereon. The substrate support 102 may be coupled to ground, a DC power source, an AC power source, or an RF power source. The substrate support 102 may be mounted on a shaft 104 which may be rotatable and/or linearly actuatable.

The target assembly 101 may be electrically isolated from the chamber walls by an insulated spacer or seal 110. The target assembly 101 may comprise a backing plate 105 coupled to a sputtering target 106. In one embodiment, the backing plate 105 may comprise aluminum. In another embodiment, the backing plate 105 may comprise copper. In another embodiment, the backing plate 105 may comprise stainless steel.

The sputtering target 106 may be bonded to the backing plate 105. In one embodiment, the sputtering target 106 may comprise an insulating material. In another embodiment, the sputtering target 106 may comprise titanium nitride. In another embodiment, the sputtering target 106 may comprise tantalum nitride. Suitable bonding materials that may be used contain elastomers. In one embodiment, the bonding material may comprise a metallic material. In another embodiment, the bonding material may comprise soldering material. In another embodiment, the bonding material may comprise a low melting point material. The bonding material may be vacuum compatible as it may be exposed to vacuum during processing.

A magnetron 107 may be disposed behind the backing plate 105. The magnetron 107 may have a plurality of magnets 108 that produce a magnetic field 111 that extends into the processing area in front of the sputtering target 106. The magnetic field 111 may concentrate the ions in the plasma to the magnetic field 111 such that the greatest amount of target erosion occurs in the areas of the target 106 contained in the magnetic field 111.

RF current, when applied to the backing plate 105 from a power source 112, travels along the outside surface of the electrically conductive backing plate 105. Thus, the RF current may travel along the entire backside of the sputtering target 106. The RF current may capacitively couple through the target everywhere corresponding to the backing plate 105, however, at every location where the backing plate 105 is bonded to the sputtering target 106, RF current may capacitively transmit through the sputtering target 106 in a greater amount. The RF current will contribute to the plasma formation, creating a plasma cloud 113, and could lead to a decrease in the benefits of the magnetic field by generating higher concentrations of plasma in undesired areas. The plasma non-uniformity may lead to non-uniform sputtering target 106 erosion.

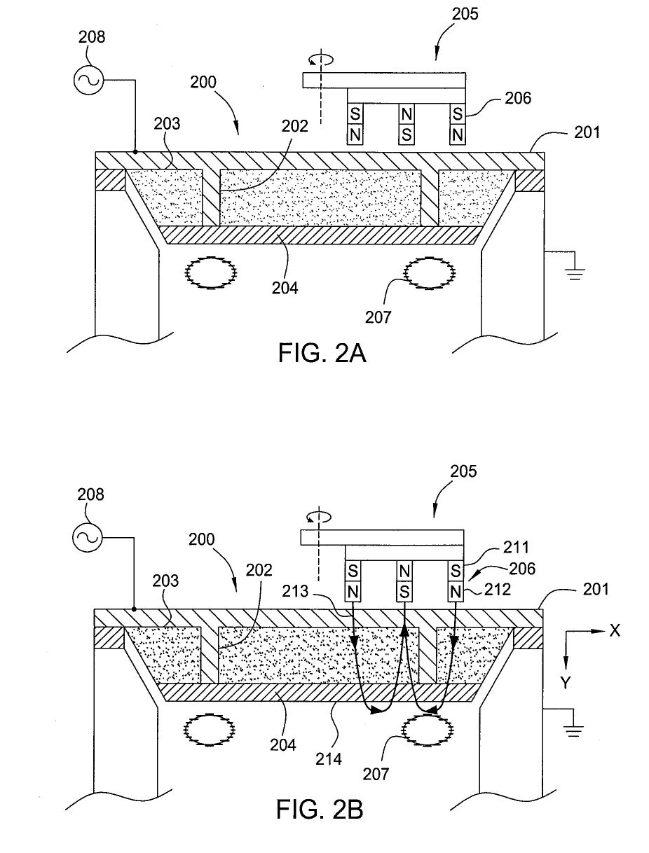

FIG. 2A is a cross sectional view of a target assembly 200 according to one embodiment of the invention. The target assembly 200 generally includes a backing plate body 201, a fin 202 extending from the backing plate body 201, a filler material 203, and a target 204 to be sputtered. The fin 202 may provide the electrical contact between the sputtering target 204 and the backing plate body 201. In one embodiment, the fin 202 may have a thickness between about 50% and 90%, the width of the backing plate body 201. The thickness of the fin 202 is related to the thickness of the sputtering target 204. In one embodiment, the sputtering target 204 is thinnest in the location coupled to the fin 202.

A bonding layer, such as an adhesive or a metal containing solder, may be used to couple the target 204 to the filler material 203, the fin 202, or both. A magnetron 205 containing a number of magnets 206 may be positioned opposite the backing plate body 201 from the target 204 and rotated about a central axis of the backing plate body 201. A power source 208 may be coupled to the backing plate body 201. In one embodiment, the power source 208 may be an RF power source 208.

In one embodiment, the backing plate body 201 and fin 202 may be made of substantially the same material. Suitable materials for the backing plate body 201 and the fin 202 may include copper, copper alloys, stainless steel, aluminum, aluminum alloys, or other electrically conductive material. In one embodiment, the backing plate body 201 may be machined to form the fin 202. In another embodiment, the fin 202 may be a separate piece coupled to the backing plate body 201. The fin 202 may be substantially symmetrical and centered on the backing plate body 201. The fin 202 may have a substantially circular shape. In one embodiment, the fin 202 may comprise a unitary piece of material. In another embodiment, the fin 202 may comprise a plurality of pieces arranged in a substantially circular shape around the axis of the backing plate body 201. In one embodiment, the target 204 may comprise a dielectric material, such as aluminum oxide (Al₂O₃), titanium nitride, tantalum nitride, silicon dioxide, silicon dielectrics, or other material.

In the embodiment shown in FIG. 2A, the sputtering target 204 is spaced from the backing plate body 201 by filler material 203. In one embodiment the filler material 203 may be a dielectric material having a dielectric constant between about 2 and 50. In another embodiment, the filler material 203 may comprise quartz. In another embodiment, the filler material 203 may have a dielectric constant lower than that of the target 204 in order to reduce the amount of power being passed to the target 204 in the areas of the target 204 that are covered in the filler material 203.

The fin 202 may generally be used to facilitate transmission of an RF signal from the RF power source 208 to a specific location on the target 204. The RF signal travels through the backing plate body 201 to the fin 202. The fin 202 then transmits the RF signal to the target 204. The filler material 203 provides a resistance to the RF signal, due to its low capacitance, and limits the transmission of the RF signal to other areas of the target 204. The filler material 203 lowers the amount of plasma being formed from areas of the target 204 not coupled to the fin 202. The fin 202 allows for precise transmission of the RF signal to a specific area of the target 204.

Transmitting the RF signal to a specific location on the target 204 may concentrate plasma into an area of enhanced plasma coupling 207. By creating an area of enhanced plasma coupling 207 it may be less likely for plasma to travel and become concentrated at other areas of the target 204. Not allowing the plasma to travel will limit the amount of unexpected erosion of the target 204 and damage to the processing chamber. Concentrating the plasma into specific areas may also help to facilitate a more efficient and complete use of the target 204 and limit erosion to desired areas of the target 204. The area of enhanced plasma coupling may be where the most material is sputtered from the target 204. The magnetron 205 may assist in controlling the plasma concentration and position of the area of increased plasma coupling 207. The fin 202 may be sized such that the areas of enhanced plasma coupling 207 are positioned to facilitate an even distribution of material onto the substrate being processed.

In one embodiment, the target assembly 200 may not contain a filler material 203. A gap may be created between the backing plate body 201 and target 204, and the target 204 may be coupled to the ends of the fin 202. In one embodiment, the gap may be evacuated or filled with a gas. In another embodiment, filler material 203 may be removed near a center of the backing plate body 201 from an area encircled by the fin 202 while leaving the filler material 203 near the edges of the backing plate body 201. In yet another embodiment, the filler material 203 may be removed near the edges of the backing plate body 201 while the filler material 203 near the center of the backing plate body 201 is maintained.

FIG. 2B is a cross sectional view of the target assembly 200 of FIG. 2A with a magnetic field 213 illustratively shown. The magnetron 205 may consist of two or more magnets 206 generally consisting of a north pole 212 and south pole 211. In one embodiment, a first magnet 206 is positioned with the south pole 211 of the magnet 206 facing the backing plate body 201. An adjacent second magnet 206 substantially surrounds the first magnet 206 and is positioned such that the north pole 212 of the magnet 206 is facing the backing plate body 201. Due to the proximity of the magnets 206 a magnetic field 213 is created. In one embodiment, the magnetic field 213 may travel through the target assembly 200. The magnetic field 213 is positioned between the north pole 212 of the first magnet 206 and the south pole 211 of the second magnet 206. The magnetic field 213 may have components directed in both the x direction which is parallel to the target sputtering surface 214 and y direction which is perpendicular to the target sputtering surface 214. A center of the fin 202 may be substantially aligned and centered in the magnetic field where the components of the magnetic field in the x direction are of a larger magnitude than the components in the y direction, as shown in FIG. 2B. In another embodiment, a center of the fin 202 may be substantially aligned and centered in the magnetic field where the components of the magnetic field parallel to a width of the backing plate body 201 are of a larger magnitude than the components perpendicular to the width of the backing plate body 201.

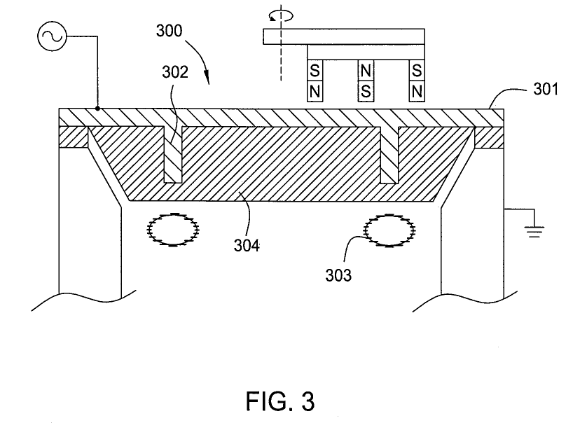

FIG. 3 is a cross sectional view of one embodiment of a target assembly 300. The target assembly 300 comprises a backing plate 301, having a fin 302 extending from a surface thereof, bonded to a sputtering target 304. Suitable materials for the backing plate body 301 and the fin 302 may include copper, copper alloys, stainless steel, aluminum, aluminum alloys, or other electrically conductive material. In one embodiment, the backing plate body 301 may be machined to form the fin 302. In another embodiment, the fin 302 may be a separate piece coupled to the backing plate body 301. The fin 302 may be substantially symmetrical and centered on the backing plate body 301. The fin 302 may have a substantially circular shape. In one embodiment, the fin 302 may comprise a unitary piece of material. In another embodiment, the fin 302 may comprise a plurality of pieces arranged in a substantially circular shape around the axis of the backing plate body 301.

The sputtering target 304 may be shaped to couple to both the backing plate 301 and fins 302. The use of a shaped target 304 may be beneficial when the dielectric constant of the target 304 is sufficiently low that use of a filler material is impractical. The shaped target 304 may be machined, or otherwise formed to match the profile of the backing plate body 301 and fin 302. Since RF signals transfer capacitively, the RF signal may be more likely to transmit through areas where the shaped target 304 is thinner because of the higher capacitance in that area. Increased areas of plasma coupling 303 may be created where the RF signal transmits more easily through the target 304.

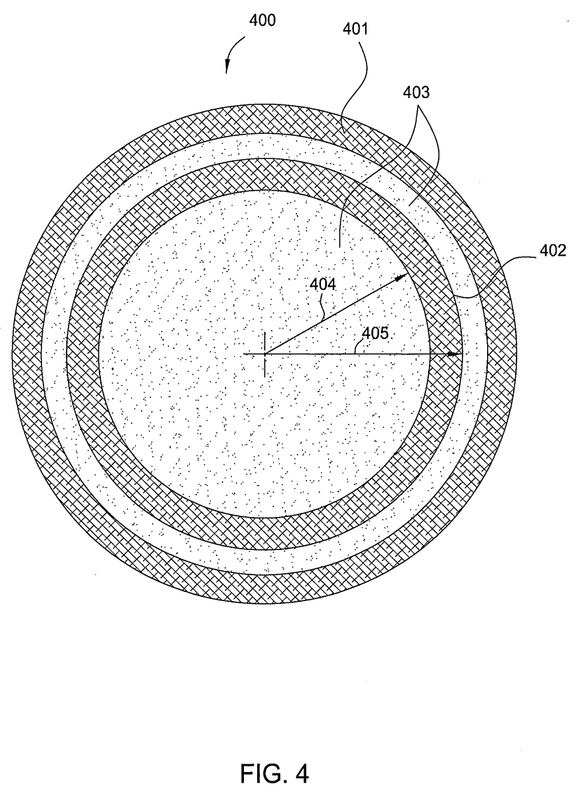

FIG. 4 is a bottom view of one embodiment of a target assembly 400 with the target removed for clarity. In this embodiment, a backing plate 401 is substantially circular. A fin 402 is substantially cylindrical having a first radius 404, defining an inner surface, and a second radius 405, defining an outer surface. In one embodiment, the first radius 404 may be smaller than the second radius 405. A filler material 403 may be coupled to the backing plate body 401, the inner surface of the fin 402, and the outer surface of the fin 402. A portion of the backing plate body 401 near the edge of the backing plate body 401 may be substantially free of filler material 403. While shown as a continuous piece of material, it is to be understood that the fin 402 may comprise one or more pieces of material coupled.

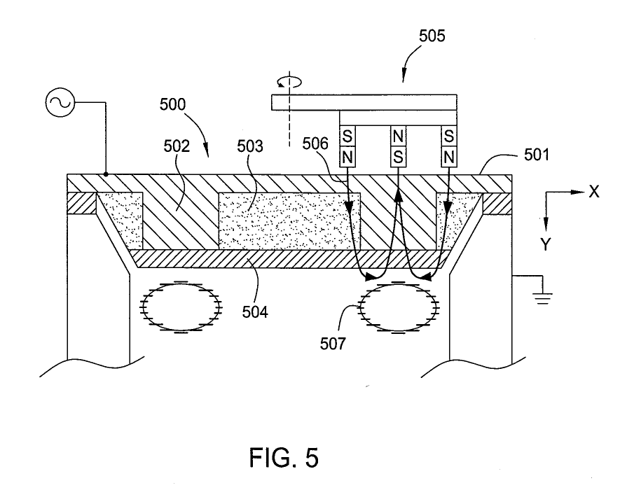

FIG. 5 is a cross sectional view of another embodiment of a target assembly 500 with magnetic fields 506 illustratively shown. In the embodiment shown in FIG. 5, a fin 502 may have a thickness between about 50% and 90%, the width of a backing plate body 501. The fin 502 may encompass an area where more than one magnetic field 506 is created by a magnetron 505. The fin 502 may also create a larger area of enhanced plasma coupling 507 which may create a larger area of the target 504 where material will be most likely to sputter from. The center of the fin 502 may be substantially positioned between adjacent magnetic fields 506. In one embodiment, a filler material 503 may be coupled between the backing plate body 501 and the fin 502 to substantially fill the space between the target 504 and the backing plate body 501.

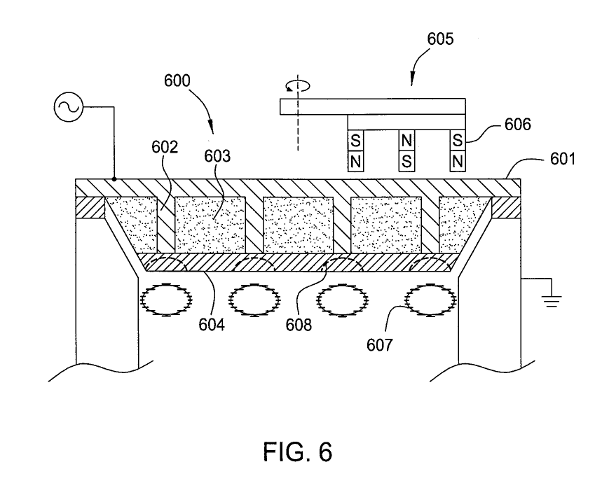

FIG. 6 is a cross sectional view of another embodiment of a target assembly 600. In this embodiment, multiple fins 602 extend from the backing plate body 601. In one embodiment, a wider magnetron 605, comprising several magnets 606, may be used to create a number of magnetic fields aligned with each fin 602. In another embodiment, multiple magnetrons 605 may be used. The multiple magnetrons or multiple magnetic fields may create multiple areas of enhanced plasma coupling 607. The areas of enhanced plasma coupling 607 may permit the most material to be sputtered from the target 604 thus create multiple erosion grooves 608 (shown in phantom). Having multiple erosion grooves 608 may be useful for sputtering a larger portion of the target 604 before it is replaced. A filler material 603 may be coupled between the backing plate body 601 and the fins 602 to substantially fill the space between the target 604 and the backing plate body 601.

The sputtering target assemblies described herein may be refurbished when necessary. For example, when the sputtering target has reached its usable life, the sputtering target may be removed from the backing plate and/or the filler material. The bonding material may also be removed. Thereafter, a new sputtering target may be bonded to the backing plate and/or the filler material. In one embodiment, the target may be removed and then the sputtered material may be replaced such that the used target is itself refurbished and then re-bonded to the backing plate and/or filler material. Additionally, the filler material may be replaced when necessary. During the refurbishment process, the used sputtering target is removed from the backing plate and/or filler material. Additionally, the bonding material may be removed. A new sputtering target or a refurbished sputtering target (i.e., a used sputtering target having sputtered material replaced such that the used target approximates the shape and/or density of a new sputtering target) is then bonded to the backing plate and/or filler material.

The embodiments of the invention described above provide for effective plasma concentration and distribution management. Deposition and erosion profiles may be more consistent and readily repeatable using the embodiments of the invention.

While the foregoing is directed to embodiments of the present invention, other and further embodiments of the invention may be devised without departing from the basic scope thereof, and the scope thereof is determined by the claims that follow.

What is claimed is:

1. A sputtering target assembly, comprising:
a backing plate body having one or more fins centered and coupled thereon, the one or more fins comprising:
an inner surface;
an outer surface; and
a bottom surface;
a filler material coupled to the backing plate body, the inner surface of the one or more fins, and outer surface of the one or more fins; and
a sputter target coupled to the filler material and bottom surface of the one or more fins.

2. The assembly of claim 1, wherein the backing plate body has a plurality of fins, wherein each fin of the plurality of fins is spaced a first distance from an adjacent fin, wherein the first distance is between about 2 to 5 times the thickness of the sputter target.

3. The assembly of claim 1, wherein the sputter target comprises the same material as the filler material.

4. The assembly of claim 1, further comprising a bonding layer coupled between the target, the one or more fins, and the filler material, wherein the sputter target does not comprise the same material as the filler material.

5. A sputtering target assembly, comprising:
a backing plate body having one or more fins configured to contact a sputter target that is centered and coupled thereon, the one or more fins comprising:
an inner surface;
an outer surface; and
a bottom surface; and
a sputter target coupled to the backing plate body, the sputter target having one or more recesses configured to receive the one or more fins.

6. The assembly of claim 5, wherein the backing plate body has a plurality of fins configured to contact a sputter target, each fin comprising:
an inner surface;
an outer surface; and
a bottom surface.

7. The assembly of claim 6, wherein each fin of the plurality of fins is spaced a first distance from an adjacent fin, wherein the first distance is between about 2 to 5 times the thickness of a portion of the sputter target.

8. The assembly of claim 5, further comprising a bonding layer coupled between the target, the one or more fins, and the backing plate body.

9. An RF magnetron sputtering apparatus, comprising:
a backing plate body having a substantially planar first surface, the backing plate body having one or more first fins extending from a second surface of the backing plate body, the second surface being opposite the first surface;
a sputter target coupled to the one or more first fins; and
a magnetron rotatable about a center axis of the backing plate body and capable of producing a first magnetic field, the magnetron positioned such that a center of each fin of the one or more first fins is substantially aligned with a location where components of the first magnetic field parallel to the first surface of the backing plate body are of a larger magnitude than the components of the first magnetic field perpendicular to the first surface of the backing plate body.

10. The apparatus of claim 9, wherein the sputter target is coupled to the second surface of the backing plate body.

11. The apparatus of claim 9, further comprising a filler material coupled to the second surface of the backing plate body, a portion of each fin of the one or more first fins, and the sputter target.

12. The apparatus of claim 9, further comprising an RF power source coupled to the backing plate.

13. The apparatus of claim 9, wherein the magnetron produces a second magnetic field, and wherein one or more second fins are positioned so that portions of the one or more second fins are substantially aligned where components of the first and second magnetic fields parallel to the first surface of the backing plate body are of a larger magnitude than the components of the first and second magnetic fields perpendicular to the first surface of the backing plate body.

14. The apparatus of claim 9, wherein a plurality of first fins extend from the second surface of the backing plate body and are coupled to the sputter target.

15. The apparatus of claim 14, wherein the magnetron produces a plurality of magnetic fields, and wherein each fin of the plurality of first fins is positioned so a center of the fin is substantially aligned where components of one of the plurality of magnetic fields parallel to the first surface of the backing plate body are of a larger magnitude than the components of the one of the plurality of magnetic fields perpendicular to the first surface of the backing plate body.

16. The apparatus of claim 14, wherein each fin of the plurality of first fins is spaced a first distance from an adjacent fin, wherein the first distance is between about 2 to 5 times the thickness of a portion of the sputter target.

17. The apparatus of claim 9, further comprising a bonding layer coupled between the target and the one or more first fins.

18. A method of assembling a sputter target assembly, comprising:
applying bonding material to one or more of a backing plate body and a sputtering target; and
compressing the backing plate body and sputtering target together, the backing plate body having one or more fins extending from a first surface thereof and substantially circumscribing the center axis of the backing plate body.

19. The method of claim 18 further comprising:
coupling a filler material to the backing plate body and adjacent a portion of the one or more fins.

20. The method of claim 18, wherein the sputtering target is shaped to receive the one or more fins and is coupled to both the one or more fins and the backing plate body.
